(19) United States
(12) Patent Application Publication
(10) Pub. No.: US 2026/0303098 A1
(43) Pub. Date: Oct. 1, 2026

(54) MEMRISTOR-BASED BOOLEAN LOGIC CIRCUIT, CONTROL METHOD, AND BOOLEAN LOGIC OPERATION DEVICE

(71) Applicant: HUAZHONG UNIVERSITY OF SCIENCE AND TECHNOLOGY, Hubei (CN)

(72) Inventors: Xingsheng Wang, Hubei (CN); Fang Cheng, Hubei (CN); Zhouchao Gan, Hubei (CN); Xiangshui MIAO, Hubei (CN)

(73) Assignee: HUAZHONG UNIVERSITY OF SCIENCE AND TECHNOLOGY, Hubei (CN)

(21) Appl. No.: 19/369,307

(22) Filed: Oct. 26, 2025

(30) Foreign Application Priority Data
Mar. 26, 2025 (CN) 202510361062.3

(51) Int. Cl. H03K 19/21; H03K 19/094

(52) U.S. Cl. CPC H03K 19/21; H03K 19/094

(57) ABSTRACT

Disclosed are a memristor-based Boolean logic circuit, a control method, and a Boolean logic operation device. The Boolean logic circuit includes a memristor M₁, a memristor M₂, a first NMOS transistor, a second NMOS transistor, a resistor, and a voltage comparator. By applying a voltage Vᵣ to control terminals T₁ and T₂ respectively, applying a gate voltage corresponding to a logical value a to a gate of the first transistor, applying a gate voltage corresponding to a logical value c to a gate of the second transistor, and grounding a control terminal T₃, a corresponding Boolean logic operation result may be obtained at an output terminal of the voltage comparator. The present disclosure fully utilizes the resistance state characteristics of memristors and the switching characteristics of transistors, and by setting the values of logical values a, b, c, d, arbitrary Boolean logic operations with fewer operation steps may be implemented.

### CROSS-REFERENCE TO RELATED APPLICATION

This application claims the priority benefit of China application serial no. 202510361062.3, filed on Mar. 26, 2025. The entirety of the above-mentioned patent application is hereby incorporated by reference herein and made a part of this specification.

### BACKGROUND

### Technical Field

The present disclosure pertains to microelectronic devices, and more specifically, relates to a memristor-based Boolean logic circuit, a control method, and a Boolean logic operation device.

### Description of Related Art

Conventional computers employ the Von Neumann architecture, wherein computation and storage functions are executed separately by a processing unit and a storage unit, respectively.

These two units are physically distinct and communicate with each other via an interconnected bus. In the context of the era of artificial intelligence and big data, the exponential growth of data has imposed higher demands on the information processing capabilities of computers. The computational bottlenecks inherent in conventional architectures have become increasingly prominent. On one hand, the computational frequency of processors significantly outpaces the access speed of memory, resulting in a mismatch known as the “memory wall” issue. On the other hand, data processing necessitates frequent transfer and read/write operations, thereby imposing a substantial burden on the bus and consuming a considerable portion of power and time due to the transportation of data. The in-memory computing technology is considered a key approach to addressing these issues. By integrating data computation units and storage units, it is possible to achieve in-situ logical computation and storage, thus avoiding frequent data transportation and significantly enhancing computational parallelism.

A memristor is a type of storage device capable of switching between high and low resistance states within its resistive layer material through the application of an electric field.

Owing to the inherent non-volatile characteristics of the memristor, compact device size, fast read/write speeds, low power consumption, and compatibility with CMOS technology, the memristor provides a hardware foundation for research in in-memory computing. In terms of digital logic, by mapping logical values to physical quantities such as resistance and voltage, and configuring port voltages according to computational requirements, the memristor may undergo corresponding resistance state transitions under specific conditions to perform logical operations.

However, existing memristor-based logical circuits typically require the combination and arrangement of multiple basic Boolean logic operations to achieve complete Boolean logic computation, particularly for more complex logic operations. For instance, the implementation of NAND logic operations necessitates first performing an AND logic operation through control operations, followed by an inversion of the AND logic result via NOT control operations. Such method involves numerous operational steps and is relatively complex to execute.

### SUMMARY

In view of the above defects or needs of improvement for the existing technology, the present disclosure provides a memristor-based Boolean logic circuit, a control method and a Boolean logic operation device, aiming to solve the technical problem that operations are relatively complex when implementing complete Boolean logic operations in the existing technology.

To achieve the above purpose, in a first aspect, the present disclosure provides a memristor-based Boolean logic circuit, including: a memristor M₁, a memristor M₂, a first NMOS transistor, a second NMOS transistor, a resistor and a voltage comparator.

A positive electrode of the memristor M₁ serves as a control terminal T₁, and a negative electrode is connected to a source of the first NMOS transistor. A positive electrode of the memristor M₂ serves as a control terminal T₂, and a negative electrode is connected to a source of the second NMOS transistor. Drains of the first NMOS transistor and the second NMOS transistor are both connected to one end of the resistor, and the other end of the resistor serves as a control terminal T₃. A positive terminal of the voltage comparator is connected to a common node of the memristor M₁, the memristor M₂ and the resistor. A first transistor and a second transistor are identical. The memristor M₁ and the memristor M₂ are identical. A resistance value of the resistor is a low resistance state value of the memristor.

When performing Boolean logic operations, the memristor M₁ is configured to store a logical value b. A negative terminal of the voltage comparator is configured to connect to a reference voltage V_{ref}. The memristor M₂ is configured to store a logical value d. A control terminal T₁ and a control terminal T₂ are respectively configured to connect to a voltage Vᵣ. A gate of the first transistor is configured to connect to a gate voltage corresponding to a logical value a. A gate of the second transistor is configured to connect to a gate voltage corresponding to a logical value c. The control terminal T₃ is used for grounding. An output terminal of the voltage comparator is configured to output a corresponding Boolean logic operation result.

V_{ref} and Vᵣ satisfy: (R_{H}+R_{L})Vᵣ/(2R_{H}+R_{L})<V_{ref}<2Vᵣ/3, wherein R_{H} and R_{L} are respectively a high resistance state value and the low resistance state value of the memristor; a gate voltage corresponding to a logical value 0 is a voltage V_{G} which is less than a transistor enabling voltage, and a gate voltage corresponding to a logical value 1 is a voltage V_{DD} which is greater than or equal to the transistor enabling voltage.

Further preferably, when the Boolean logic operation is a true logic operation, a is 1, c is 0 or 1, b is 1, and d is 0 or 1.

When the Boolean logic operation is a false logic operation, a is 0, c is 0, b is 0 or 1, and d is 0 or 1.

When the Boolean logic operation is a p logic operation, a is p, c is 0, b is 1, and d is 0 or 1.

When the Boolean logic operation is a q logic operation, a is 0, c is q, b is 0 or 1, and d is 1.

When the Boolean logic operation is a negation of p, a is a logical negation of p, c is 0,
b is 1, and d is 0 or 1.

When the Boolean logic operation is a negation of q, a is 0, c is a logical negation of q,
b is 0 or 1, and d is 1.

When the Boolean logic operation is an AND logic operation of logical values p and q, a is p, c is 0, b is q, and d is 0 or 1.

When the Boolean logic operation is an NAND logic operation of the logical values p and q, a is a logical negation of p, c is a logical negation of q, b is 1, and d is 1.

When the Boolean logic operation is an OR logic operation of the logical values p and q, a is p, c is q, b is 1, and d is 1.

When the Boolean logic operation is an NOR logic operation of the logical values p and q, a is a logical negation of p, c is 0, b is a logical negation of q, and d is 0 or 1.

When the Boolean logic operation is a material implication logic operation of the logical values p and q, a is a logical negation of p, c is q, b is 1, and d is 1.

When the Boolean logic operation is a negative material implication logic operation of the logical values p and q, a is p, c is 0, b is a logical negation of q, and d is 0 or 1.

When the Boolean logic operation is a converse material implication logic operation of the logical values p and q, a is p, c is a logical negation of q, b is 1, and d is 1.

When the Boolean logic operation is a converse negative material implication logic operation of the logical values p and q, a is a logical negation of p, c is 0, b is q, and d is 0 or 1.

When the Boolean logic operation is an XOR logic operation of the logical values p and q, a is a logical negation of p, c is p, b is q, and d is a logical negation of q.

When the Boolean logic operation is an XNOR logic operation of the logical values p and q, a is p, c is a logical negation of p, b is q, and d is a logical negation of q.

In a second aspect, the present disclosure provides a control method for the above Boolean logic circuit, including a Boolean logic operation: the voltage Vᵣ is applied to the control terminal T₁ and the control terminal T₂ respectively, the gate voltage corresponding to the logical value a is applied to the gate of the first transistor, the gate voltage corresponding to the logical value c is applied to the gate of the second transistor, the control terminal T₃ is grounded, and the corresponding Boolean logic operation result is read at the output terminal of the voltage comparator.

The memristor M₁ stores the logical value b, and the memristor M₂ stores the logical value d. The negative terminal of the voltage comparator is connected to the reference voltage V_{ref}. V_{ref} and Vᵣ satisfy: (R_{H}+R_{L})Vᵣ/(2R_{H}+R_{L})<V_{ref}<2Vᵣ/3, wherein R_{H} and R_{L} are the high resistance state value and the low resistance state value of the memristor respectively; the gate voltage corresponding to the logical value 0 is the voltage V_{G} less than the transistor enabling voltage, and the gate voltage corresponding to the logical value 1 is the voltage V_{DD} greater than or equal to the transistor enabling voltage.

Further preferably, the above control method further includes: an initialization memristor operation executed before the Boolean logic operation.

The initialization memristor operation includes: writing the logical value b into the memristor M₁, and writing the logical value d into the memristor M₂.

The corresponding logical value is written by setting high and low resistance states of the memristor; the high resistance state of the memristor corresponds to the logical value 0, and the low resistance state corresponds to the logical value 1.

Further preferably, the operation of writing the logical value b into the memristor M₁ includes the following:

When b is 0, the control terminal T₁ is grounded, the control terminal T₂ is set to a floating state, and a fixed voltage V_{q} is connected to the control terminal T₃. The voltage V_{DD} is applied to the gates of the first transistor and the second transistor, thereby writing the logical value b into the memristor M₁.

When b is 1, a fixed voltage Vₚ is connected to the control terminal T₁, the control terminal T₂ is set to the floating state, and the control terminal T₃ is grounded. The voltage V_{DD} is applied to the gates of the first transistor and the second transistor, thereby writing the logical value b into the memristor M₁.

V_{q}>2|Vᵣₑₛₑₜ|; Vₚ>(R_{H}+R_{L})Vₛₑₜ/R_{H}, wherein Vᵣₑₛₑₜ is a threshold for the memristor to convert from the low resistance state to the high resistance state; Vₛₑₜ is a threshold for the memristor to convert from the high resistance state to the low resistance state; R_{H} is the high resistance state value of the memristor; R_{L} is the low resistance state value of the memristor.

Further preferably, the operation of writing the logical value d into the memristor M₂ includes the following:

When d is 0, the control terminal T₁ is set to the floating state, the control terminal T₂ is grounded, and the fixed voltage V_{q} is connected to the control terminal T₃. The voltage V_{DD} is applied to the gates of the first transistor and the second transistor, thereby writing the logical value d into the memristor M₂.

When d is 1, the control terminal T₁ is set to the floating state, the fixed voltage Vₚ is connected to the control terminal T₂, and the control terminal T₃ is grounded. The voltage V_{DD} is applied to the gates of the first transistor and the second transistor, thereby writing the logical value d into the memristor M₂.

V_{q}>2|Vᵣₑₛₑₜ|; Vₚ>(R_{H}+R_{L})Vₛₑₜ/R_{H}, wherein Vᵣₑₛₑₜ is the threshold for the memristor to convert from the low resistance state to the high resistance state; Vₛₑₜ is the threshold for the memristor to convert from the high resistance state to the low resistance state; R_{H} is the high resistance state value of the memristor; R_{L} is the low resistance state value of the memristor.

Further preferably, when the Boolean logic operation is a true logic operation, a is 1, c is 0 or 1, b is 1, and d is 0 or 1.

When the Boolean logic operation is a false logic operation, a is 0, c is 0, b is 0 or 1, and d is 0 or 1.

When the Boolean logic operation is a p logic operation, a is p, c is 0, b is 1, and d is 0 or 1.

When the Boolean logic operation is a q logic operation, a is 0, c is q, b is 0 or 1, and d is 1.

When the Boolean logic operation is a negation of p, a is a logical negation of p, c is 0, b is 1, and d is 0 or 1.

When the Boolean logic operation is a negation of q, a is 0, c is a logical negation of q, b is 0 or 1, and d is 1.

When the Boolean logic operation is an AND logic operation of the logical values p and q, a is p, c is 0, b is q, and d is 0 or 1.

When the Boolean logic operation is an NAND logic operation of the logical values p and q, a is a logical negation of p, c is a logical negation of q, b is 1, and d is 1.

When the Boolean logic operation is an OR logic operation of the logical values p and q, a is p, c is q, b is 1, and d is 1.

When the Boolean logic operation is an NOR logic operation of the logical values p and q, a is a logical negation of p, c is 0, b is a logical negation of q, and d is 0 or 1.

When the Boolean logic operation is a material implication logic operation of the logical values p and q, a is a logical negation of p, c is q, b is 1, and d is 1.

When the Boolean logic operation is a negative material implication logic operation of the logical values p and q, a is p, c is 0, b is a logical negation of q, and d is 0 or 1.

When the Boolean logic operation is a converse material implication logic operation of the logical values p and q, a is p, c is a logical negation of q, b is 1, and d is 1.

When the Boolean logic operation is a converse negative material implication logic operation of the logical values p and q, a is a logical negation of p, c is 0, b is q, and d is 0 or 1.

When the Boolean logic operation is an XOR logic operation of the logical values p and q, a is a logical negation of p, c is p, b is q, and d is a logical negation of q.

When the Boolean logic operation is an XNOR logic operation of the logical values p and q, a is p, c is a logical negation of p, b is q, and d is a logical negation of q.

In a third aspect, the present disclosure provides a Boolean logic operation device, including: a controller and the Boolean logic circuit provided in the first aspect of the present disclosure.

The controller is configured to execute the control method provided in the second aspect of the present disclosure.

In a fourth aspect, the present disclosure provides a control system, including: a memory and a processor. The memory stores a computer program. The processor executes the control method provided in the second aspect of the present disclosure when executing the computer program.

In a fifth aspect, the present disclosure further provides a computer-readable storage medium. The computer-readable storage medium includes a stored computer program, wherein when the computer program is executed by a processor, the computer program controls a device where the storage medium is located to execute the control method provided in the second aspect of the present disclosure.

In a sixth aspect, the disclosure further provides a computer program product, including a computer program/instructions. When the computer program/instructions are executed by a processor, the control method provided in the second aspect of the present disclosure is implemented.

Overall, through the above technical solutions conceived by the present disclosure, the following advantageous effects may be achieved:

1. The present disclosure provides a memristor-based Boolean logic circuit, including the memristor M₁, the memristor M₂, the first NMOS transistor, the second NMOS transistor, the resistor and the voltage comparator. By respectively applying the voltage Vᵣ to the control terminal T₁ and the control terminal T₂, applying the gate voltage corresponding to the logical value a to the gate of the first transistor, applying the gate voltage corresponding to the logical value c to the gate of the second transistor, and grounding the control terminal T₃, it is possible to obtain the corresponding Boolean logic operation result at the output terminal of the voltage comparator; wherein V_{ref} and Vᵣ satisfy: (R_{H}+R_{L})Vᵣ/(2R_{H}+R_{L})<V_{ref}<²Vᵣ/3, thus ensuring correct execution of logic operations and accuracy of reading results. The present disclosure fully utilizes the resistance state characteristics of memristors and the switching characteristics of transistors. Moreover, by setting the values of the logical values a, b, c, and d, it is possible to implement arbitrary Boolean logic operations with fewer operation steps, the operation is relatively simple, and supports the implementation of complete Boolean logic operations.

2. The Boolean logic circuit provided by the present disclosure ensures that the resistance states of the memristor M₁ and the memristor M₂ remain unchanged during the process of logical computation. The entire operation is non-destructive, which contributes to preserving the integrity of the input information.

3. The Boolean logic circuit provided by the present disclosure requires fewer operational steps, operates at a higher speed, and consumes less power. The Boolean logic circuit of the present disclosure features a simplified peripheral circuit configuration, making the Boolean logic circuit suitable for application to in-memory computing and the design of digital logic units. Additionally, the Boolean logic circuit is easy to cascade, offers significant advantages for parallel computing, and supports large-scale parallel computation.

### BRIEF DESCRIPTION OF THE DRAWINGS

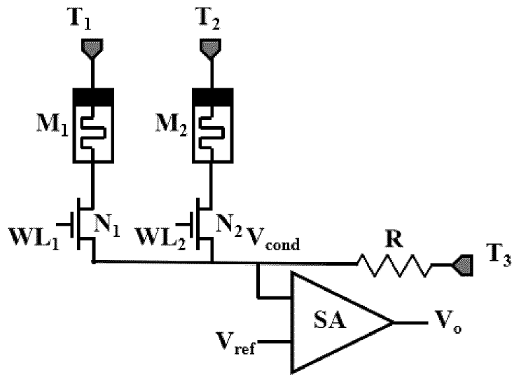

The FIG. 1s a schematic diagram of results of a memristor-based Boolean logic circuit provided by an embodiment of the present disclosure.

### DESCRIPTION OF THE EMBODIMENTS

To make the objectives, technical solutions and advantages of the present disclosure clearer, the present disclosure is further described in detail below in combination with the accompanying drawings and embodiments. It should be understood that the specific embodiments described herein are merely configured to explain the present disclosure and are not configured to limit the present disclosure. In addition, the technical features involved in the various embodiments of the present disclosure described below may be combined with each other as long as they do not constitute conflicts with each other.

To achieve the above purpose, in a first aspect, the present disclosure provides a memristor-based Boolean logic circuit, as shown in FIGURE, including: a memristor M₁, a memristor M₂, a first NMOS transistor N₁, a second NMOS transistor N₂, a resistor R, and a voltage comparator SA.

A positive terminal of the memristor M₁ serves as a control terminal T₁, and a negative terminal is connected to a source of the first NMOS transistor. A positive terminal of memristor M₂ serves as a control terminal T₂, and a negative terminal is connected to a source of the second NMOS transistor. A gate of the first NMOS transistor is connected to a word line WL₁. A gate of the second NMOS transistor is connected to a word line WL₂. Drains of the first NMOS transistor and the second NMOS transistor are both connected to one end of the resistor, and the other end of the resistor serves as a control terminal T₃. A positive terminal of the voltage comparator is connected to a common node of the memristor M₁, the memristor M₂ and the resistor, and a negative terminal is connected to a reference voltage V_{ref}. The first transistor and the second transistor are identical. The memristor M₁ and the memristor M₂ are identical. A resistance value of the resistor is a low resistance state value of the memristor.

When performing Boolean logic operations, the memristor M₁ is configured to store the logical value b. The negative terminal of the voltage comparator is configured to connect to the reference voltage V_{ref}. The memristor M₂ is configured to store the logical value d. The control terminal T₁ and the control terminal T₂ are respectively configured to connect to the voltage Vᵣ. The gate of the first transistor is configured to connect to the gate voltage corresponding to the logical value a. The gate of the second transistor is configured to connect to the gate voltage corresponding to the logical value c. The control terminal T₃ is used for grounding. An output terminal of the voltage comparator is configured to output the corresponding Boolean logic operation result.

The memristor includes two resistance states, namely the high resistance state and the low resistance state, with corresponding resistance values of R_{H} and R_{L} respectively. The high resistance state of the memristor corresponds to the logical value 0, and the low resistance state of the memristor corresponds to the logical value 1. When a forward voltage value greater than the voltage Vₛₑₜ is applied at both terminals of the memristor, the memristor may be converted from the high resistance state to the low resistance state (i.e., a Set process of the memristor). Conversely, when a reverse voltage with an absolute value greater than |Vᵣₑₛₑₜ| is applied at both terminals of the memristor, the memristor may be converted from the high resistance state to the low resistance state (i.e., a Reset process of the memristor). Specifically, in an optional implementation, mean values of the voltage Vₛₑₜ and the voltage Vᵣₑₛₑₜ of the memristor are 0.6V and −1.2V respectively, a high resistance state value R_{H}=100kΩ, a low resistance state value R_{L}=1kΩ, and a resistance value R=1kΩ.

The Boolean logic circuit provided by the present disclosure may be regarded as a combination of two 1T1R units. By defining the inputs to this structure, all Boolean logic may be represented, rendering it a complete and reconfigurable logic set. In an alternative embodiment, the input and output definitions of the Boolean logic circuit are as shown in Table 1:

TABLE 1

| Physical variables | | | Logical value “0” | Logical value “1” |
|---|---|---|---|---|
| Input | p or q | WL₁ | V_{G} | V_{DD} |
| p or q | in | WL₂ | V_{G} | V_{DD} |
| | positive | M₁ | high resistance state | low resistance state |
| | logic | M₂ | high resistance state | low resistance state |
| | negation | WL₁ | V_{DD} | V_{G} |
| | of | WL₂ | V_{DD} | V_{G} |
| | p or q | M₁ | low resistance state | high resistance state |
| | | M₂ | low resistance state | high resistance state |
| Output | \ | Vₒ | low level | high level |

It should be noted that the gate voltage corresponding to the logical value 0 is a voltage V_{G} which is less than a transistor enabling voltage, and the gate voltage corresponding to the logical value 1 is a voltage V_{DD} which is greater than or equal to the transistor enabling voltage. When the voltage V_{G} is applied to the gate of the transistor, the transistor is not conductive; when the voltage V_{DD} is applied to the gate of the transistor, the transistor is conductive. Under normal circumstances, the voltage V_{G} is 0V, corresponding to the operation of grounding the transistor gate. For the input logical variable p or q, in positive logic (i.e., the Boolean logic operation does not involve a negation of p or q), when the gate voltage (WL₁ or WL₂) of the NMOS transistor (N₁ or N₂) is grounded, it represents the logical value “0”. When the gate voltage (WL₁ or WL₂) of the NMOS transistor (N₁ or N₂) is connected to the fixed voltage V_{DD}, it represents the logical value “1”. When the resistance state of the memristor (M₁ or M₂) is the high resistance state, it represents the logical value “0”. When the resistance state of the memristor (M₁ or M₂) is the low resistance state, it represents the logical value “1”. For the input logical variable p or q, in negative logic (involving a negation of p or q), when the gate voltage (WL₁ or WL₂) of the NMOS transistor (N₁ or N₂) is grounded, it represents the logical value “1”. When the gate voltage (WL₁ or WL₂) of the NMOS transistor (N₁ or N₂) is connected to the fixed voltage V_{DD}, it represents the logical value “0”. When the resistance state of the memristor (M₁ or M₂) is the high resistance state, it represents the logical value “1”. When the resistance state of the memristor (M₁ or M₂) is the low resistance state, it represents the logical value “0”. For the output variable Vₒ, when Vₒ is at a low level, it represents the output logical value “0”. When Vₒ is at a high level, it represents the output logical value “1”.

A voltage V_{cond} at the common node of the memristor M₁, the memristor M₂ and the resistor connected to the positive terminal of the voltage comparator change according to the variation of the resistance values of the memristor M₁ and the memristor M₂. In order to ensure correct execution of logic operations and correctly read out the result, the voltage Vᵣₑf and the voltage Vᵣ satisfy the following relationship: (R_{H}+R_{L})Vᵣ/(2R_{H}+R_{L})<V_{ref}<2Vᵣ/3. Preferably, in an optional implementation, a switching ratio of the memristor is greater than or equal to 100. It should be noted that the switching ratio of the memristor directly affects a resistance state change window of the memristor in an output column. The larger the switching ratio, the larger the resistance state change window of the memristor in the output column. When the switching ratio is greater than or equal to 100, the memristor in the output column may implement the resistance state change more accurately, thereby further improving the accuracy of computation. Under the circumstances, the above relationship may be further simplified as: 101Vᵣ/201<V_{ref}<2Vᵣ/3.

The Boolean logic circuit provided by the present disclosure is a four-input logic circuit, the output result is the result of four inputs AND-OR combination, and is expressed as: o=ab+cd. By setting the values of the logical values a, b, c, d, dimensionality reduction may be performed on the four variables to implement complete Boolean logic operations.

Specifically, in an optional implementation, when the Boolean logic operation is a true logic operation, a is 1, c is 0 or 1, b is 1, and d is 0 or 1.

When the Boolean logic operation is a false logic operation, a is 0, c is 0, b is 0 or 1, and d is 0 or 1.

When the Boolean logic operation is a p logic operation, a is p, c is 0, b is 1, and d is 0 or 1.

When the Boolean logic operation is a q logic operation, a is 0, c is q, b is 0 or 1, and d is 1.

When the Boolean logic operation is a negation of p, a is a logical negation of p, c is 0, b is 1, and d is 0 or 1.

When the Boolean logic operation is a negation of q, a is 0, c is a logical negation of q, b is 0 or 1, and d is 1.

When the Boolean logic operation is an AND logic operation of logical values p and q, a is p, c is 0, b is q, and d is 0 or 1.

When the Boolean logic operation is an NAND logic operation of logical values p and q, a is a logical negation of p, c is a logical negation of q, b is 1, and d is 1.

When the Boolean logic operation is an OR logic operation of logical values p and q, a is p, c is q, b is 1, and d is 1.

When the Boolean logic operation is an NOR logic operation of logical values p and q, a is a logical negation of p, c is 0, b is a logical negation of q, and d is 0 or 1.

When the Boolean logic operation is a material implication logic operation of logical values p and q, a is a logical negation of p, c is q, b is 1, and d is 1.

When the Boolean logic operation is a negative material implication logic operation of logical values p and q, a is p, c is 0, b is a logical negation of q, and d is 0 or 1.

When the Boolean logic operation is a converse material implication logic operation of logical values p and q, a is p, c is a logical negation of q, b is 1, and d is 1.

When the Boolean logic operation is a converse negative material implication logic operation of logical values p and q, a is a logical negation of p, c is 0, b is q, and d is 0 or 1.

When the Boolean logic operation is an XOR logic operation of logical values p and q, a is a logical negation of p, c is p, b is q, and d is a logical negation of q.

When the Boolean logic operation is an XNOR logic operation of logical values p and q, a is p, c is a logical negation of p, b is q, and d is a logical negation of q.

In a second aspect, the present disclosure provides a control method for the above Boolean logic circuit, including:

An initialization memristor operation executed before an actual Boolean logic operation:

The logical value b is written into the memristor M₁, so that logical value b is stored in the memristor M₁. The logical value d is written into the memristor M₂, so that the logical value d is stored in the memristor M₂. In an optional implementation method, corresponding logical values are written by setting the high and low resistance states of the memristor; wherein, the high resistance state of the memristor corresponds to the logical value 0, and the low resistance state corresponds to the logical value 1.

Specifically, in an optional implementation method, the operation of writing the logical value b into the memristor M₁ includes the following:

When b is 0, the control terminal T₁ is grounded, and the control terminal T₂ is set to the floating state, and the fixed voltage V_{q} is connected to the control terminal T₃. The fixed voltage V_{DD} for gating the transistors is applied to the gates of the first transistor and the second transistor. Under the circumstances, the memristor M₁ implements the Reset process and is converted into the high resistance state, thereby writing the logical value 0 into the memristor M₁.

When b is 1, the fixed voltage Vₚ is connected to the control terminal T₁, the control terminal T₂ is set to the floating state, and the control terminal T₃ is grounded. The fixed voltage V_{DD} for gating the transistors is applied to the gates of the first transistor and the second transistor. Under the circumstances, the memristor M₁ implements the Set process and is converted into the low resistance state, thereby writing the logical value 1 into the memristor M₁.

In an optional implementation method, the operation of writing the logical value d into the memristor M₂ includes the following:

When d is 0, the control terminal T₁ is set to the floating state, the control terminal T₂ is grounded, and the fixed voltage V_{q} is connected to the control terminal T₃. The fixed voltage V_{DD} for gating the transistors is applied to the gates of the first transistor and the second transistor. Under the circumstances, the memristor M₂ implements the Reset process and is converted into the high resistance state, thereby writing the logical value 0 into the memristor M₂.

When d is 1, the control terminal T₁ is set to the floating state, the fixed voltage Vₚ is connected to the control terminal T₂, and the control terminal T₃ is grounded. The fixed voltage V_{DD} for gating the transistors is applied to the gates of the first transistor and the second transistor. Under the circumstances, the memristor M₂ implements the Set process and is converted into the low resistance state, thereby writing the logical value 1 into the memristor M₂.

It should be noted that, in order to ensure that the input information on the memristor M₁ and the memristor M₂ may be normally written, the condition: V_{q}>2|Vᵣₑₛₑₜ|; Vₚ>(R_{H}+R_{L})Vₛₑₜ/R_{H} should be satisfied, wherein the voltage Vᵣₑₛₑₜ is a threshold for the memristor to convert from the low resistance state to the high resistance state; the voltage Vₛₑₜ is a threshold for the memristor to convert from the high resistance state to the low resistance state; R_{H} is a high resistance state value of the memristor; R_{L} is a low resistance state value of the memristor.

Preferably, in an optional implementation method, according to the limitation on the value range of the operating voltage, combined with the relationship between the voltage Vₛₑₜ and the voltage Vᵣₑₛₑₜ of the actually used memristor, Vₚ=1.2Vₛₑₜ; V_{q}=2.2|Vᵣₑₛₑₜ|; V_{ref}=0.6Vᵣ; Vᵣ=0.4V is selected.

### Actual Boolean Logic Operation is as Follows:

The voltage Vᵣ is applied to the control terminal T₁ and the control terminal T₂ respectively, the gate voltage corresponding to the logical value a is applied to the gate of the first transistor, the gate voltage corresponding to the logical value c is applied to the gate of the second transistor, the control terminal T₃ is grounded, and the corresponding Boolean logic operation result is read at the output terminal of the voltage comparator.

The negative terminal of the voltage comparator is connected with the reference voltage V_{ref}, wherein V_{ref} and Vᵣ satisfy: (R_{H}+R_{L})Vᵣ/(2R_{H}+R_{L})<V_{ref}<2Vᵣ/3; R_{H} and R_{L} are the high resistance state value and the low resistance state value of the memristor respectively; the gate voltage corresponding to the logical value 0 is the voltage V_{G} less than the transistor enabling voltage, and the gate voltage corresponding to the logical value 1 is the voltage V_{DD} greater than or equal to the transistor enabling voltage.

The expression for the Boolean logic operation result in the present disclosure is: o=ab+cd. The complete Boolean logic operations may be implemented by setting the values of the logical values a, b, c, d. Specifically, the reference voltage V_{ref} is applied to the negative terminal of the voltage comparator, the voltage Vᵣ is applied to the control terminal T₁ and the control terminal T₂ respectively, and the control terminal T₃ is grounded. When a=0 and c=0, the gates of the NMOS transistors N₁ and N₂ are both connected to the fixed voltage V_{G}. When a=1 and c=0, the gate of the NMOS transistor N₁ is connected to the fixed voltage V_{DD}, and the gate of the NMOS transistor N₂ is connected to the fixed voltage V_{G}. When a=0 and c=1, the gate of the NMOS transistor N₁ is connected to the fixed voltage V_{G}, and the gate of the NMOS transistor N₂ is connected to the fixed voltage V_{DD}. When a=1 and c=1, the gates of the NMOS transistor N₁ and the NMOS transistor N₂ are both connected to the fixed voltage V_{DD}. The corresponding Boolean logic operation result is obtained at the output terminal of the voltage comparator.

The specific voltage configuration is shown in Table 2:

TABLE 2

| Operation | T₁ | T₂ | T₃ | WL₁ | WL₂ |
|---|---|---|---|---|---|
| Write b | Grounded (b = 0) | Floating | V_{q} (b = 0) | V_{DD} | V_{DD} |
| | Vₚ (b = 1) | | Grounded (b = 1) | | |
| Write d | Floating | Grounded (d = 0) | V_{q} (d = 0) | V_{DD} | V_{DD} |
| | | Vₚ (d = 1) | Grounded (d = 1) | | |
| o = ab + cd | V_{read} | V_{read} | Grounded | V_{G} (a = 0) | V_{G} (c = 0) |
| | | | | V_{DD} (a = 1) | V_{DD} (c = 1) |

The related technical solution is the same as the Boolean logic circuit provided in the first aspect of the present disclosure, which will not be described redundantly here.

To make the technical solution and advantages of the present disclosure clearer, in an optional implementation, Table 3 is provided showing a table for implementing 16 types of Boolean logic operations in one step based on a memristor-based four-input logic solution. In this implementation, V_{G} is a voltage with amplitude of 0, corresponding to the operation of grounding the gate of the transistor.

TABLE 3

| | Expression | Definition | | | |
|---|---|---|---|---|---|
| Type of logic | of logic | WL₁ | WL₂ | M₁ | M₂ |
| TRUE | 1 | 1 | 0 or 1 | 1 | 0 or 1 |
| FALSE | 0 | 0 | 0 | 0 or 1 | 0 or 1 |
| COPY p | p | p | 0 | 1 | 0 or 1 |
| COPY q | q | 0 | q | 0 or 1 | 0 or 1 |
| NOT p | p̅ | p̅ | 0 | 1 | 0 or 1 |
| NOT q | q̅ | 0 | q̅ | 0 or 1 | 1 |
| AND | pq | p | 0 | q | 0 or 1 |
| NAND | p̅q̅ | p̅ | q̅ | 1 | 1 |
| OR | p + q | p | q | 1 | 1 |
| NOR | p̅ +̅ q̅ | p̅ | 0 | q̅ | 0 or 1 |
| IMP | p̅ + q | p̅ | q | 1 | 1 |
| NIMP | pq̅ | p | 0 | q̅ | 0 or 1 |
| RIMP | p + q̅ | p | q̅ | 1 | 1 |
| RNIMP | p̅q | p̅ | 0 | q | 0 or 1 |
| XOR | p̅q + pq̅ | p̅ | p | q | q̅ |
| NXOR | pq + p̅q̅ | p | p̅ | q | q̅ |

The specific operations are as follows:

When the Boolean logic operation is a true logic operation, the logical expression is 1, under the circumstances, a=1, c=0 or 1, b=1, and d=0 or 1. Specifically, before performing the Boolean logic operation, the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. The fixed voltage V_{DD} is applied to the gate of the first transistor, the voltage with amplitude of 0 or the fixed voltage V_{DD} is applied to the gate of the second transistor, which is not limited here. Under the circumstances, a current flowing through the fixed resistor R is large, V_{cond}>V_{ref}, a voltage output by the voltage comparator is at the high level, that is, the logic operation result is always 1, thus implementing true logic.

When the Boolean logic operation is a false logic operation, the logical expression is 0, under the circumstances, a is 0, c is 0, b is 0 or 1, and d is 0 or 1. Specifically, before performing the Boolean logic operation, the memristor M₁ is preset to the high resistance state or the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. The gates of the first transistor and the second transistor are grounded. Under the circumstances, the current flowing through the fixed resistor R is small, V_{cond}<V_{ref}, the voltage output by the voltage comparator is at the low level, that is, the logic operation result is always 0, thus implementing false logic.

When the Boolean logic operation is a p logic operation, the logical expression is p, under the circumstances, a is p, c is 0, b is 1, and d is 0 or 1. Specifically, before performing the Boolean logic operation, the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor, and the gate of the second transistor is grounded. Under the circumstances, the current flowing through the fixed resistor R changes according to the variation of the input logical value p, thereby affecting the relationship between the voltage V_{cond} and the voltage V_{ref}. When p is 0, V_{cond}<V_{ref}, the voltage output by the voltage comparator is at the low level, that is, the logic operation result is 0. When p is 1, V_{cond}>V_{ref}, the voltage output by the voltage comparator is at the high level, that is, the logic operation result is 1, thus implementing the p logic operation, and the Boolean logic operation result is p.

When the Boolean logic operation is a q logic operation, the logical expression is q, under the circumstances, a is 0, c is q, b is 0 or 1, and d is 1. Specifically, before performing the Boolean logic operation, the memristor M₁ is preset to the high resistance state or the low resistance state, which is not limited here. The memristor M₂ is preset to the low resistance state. When performing the Boolean logic operation, the voltage Vᵣ is applied to the control terminal T₁ and the control terminal T₂ respectively, and the control terminal T₃ is grounded. The gate of the first transistor is grounded. When q is 0, the gate of the second transistor is grounded. When q is 1, the fixed voltage V_{DD} is applied to the gate of the second transistor. Under the circumstances, the current flowing through the fixed resistor R changes according to the variation of the input logical value q, thereby affecting the relationship between the voltage V_{cond} and the voltage V_{ref}. When q is 0, V_{cond}<V_{ref}, the voltage output by the voltage comparator is at the low level, that is, the logic operation result is 0. When q is 1, V_{cond}>V_{ref}, the voltage output by the voltage comparator is at the high level, that is, the logic operation result is 1, thus implementing q logic operation, and the Boolean logic operation result is q.

When the Boolean logic operation is a negation of p, the logical expression is p, under the circumstances, a is a logical negation of p, c is 0, b is 1, and d is 0 or 1. Specifically, before performing the Boolean logic operation, the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 0 (negation of p is 1), the fixed voltage V_{DD} is applied to the gate of the first transistor. When p is 1 (negation of p is 0), the gate of the first transistor is grounded, and the gate of the second transistor is grounded. Under the circumstances, the current flowing through the of the fixed resistor R changes according to the variation of the input logical value p, thereby affecting the relationship between the voltage V_{cond} and the voltage V_{ref}. When p is 1, V_{cond}<V_{ref}, the voltage output by the voltage comparator is at the low level, that is, the logic operation result is 0. When p is 0, V_{cond}>V_{ref}, the voltage output by the voltage comparator is at the high level, that is, the logic operation result is 1, thus implementing the logical operation of negation of p, and the Boolean logic operation result is p.

When the Boolean logic operation is a negation of q, the logical expression is q, under the circumstances, a is 0, c is a logical negation of q, b is 0 or 1, and d is 1. Specifically, before performing the Boolean logic operation, the memristor M₁ is preset to the high resistance state or the low resistance state, which is not limited here. The memristor M₂ is preset to the low resistance state. When performing the Boolean logic operation, the voltage Vᵣ is applied to the control terminal T₁ and the control terminal T₂ respectively, and the control terminal T₃ is grounded. The gate of the first transistor is grounded. When q is 0 (negation of q is 1), the fixed voltage V_{DD} is applied to the gate of the second transistor. When p is 1 (negation of p is 0), the gate of the second transistor is grounded. Under the circumstances, the current flowing through the fixed resistor R changes according to the variation of the input logical value q, thereby affecting the relationship between the voltage V_{cond} and the voltage V_{ref}. When q is 1, V_{cond}<V_{ref}, the voltage output by the voltage comparator is at the low level, that is, the logic operation result is 0. When q is 0, V_{cond}>V_{ref}, the voltage output by the voltage comparator is at the high level, that is, the logic operation result is 1, thus implementing the logic operation of negation of q, and the Boolean logic operation result is q̅.

When the Boolean logic operation is an AND logic operation of logical values p and q, the logical expression is pq, under the circumstances, a is p, c is 0, b is q, and d is 0 or 1. Specifically, before performing the Boolean logic operation, the memristor M₁ is preset to the resistance state corresponding to the logical value q. When q is 0, the memristor M₁ is preset to the high resistance state. When q is 1, the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor, and the gate of the second transistor is grounded. Under the circumstances, the current flowing through the fixed resistor R changes according to the variation of the input logical values pq, thereby affecting the relationship between the voltage V_{cond} and the voltage V_{ref}. When pq is 0, V_{cond}<V_{ref}, the voltage output by the voltage comparator is at the low level, that is, the logic operation result is 0. When pq is 1, V_{cond}>V_{ref}, the voltage output by the voltage comparator is at the high level, that is, the logic operation result is 1, thus implementing the AND logic operation, and the Boolean logic operation result is pq.

When the Boolean logic operation is an NAND logic operation of logical values p and q, the logical expression is p̅q̅, under the circumstances, a is a logical negation of p, c is a logical negation of q, b is 1, and d is 1. Specifically, before performing the Boolean logic operation, both the memristor M₁ and the memristor M₂ are preset to the low resistance state. When performing the Boolean logic operation, the voltage Vᵣ is applied to the control terminal T₁ and the control terminal T₂ respectively, and the control terminal T₃ is grounded. When p is 1 (negation of p is 0), the gate of the first transistor is grounded. When p is 0 (negation of p is 1), the fixed voltage V_{DD} is applied to the gate of the first transistor. When q is 1 (negation of q is 0), the gate of the second transistor is grounded. When q is 0 (negation of q is 1), the fixed voltage V_{DD} is applied to the gate of the second transistor. Under the circumstances, the current flowing through the fixed resistor R changes according to the variation of the input logical values p̅q̅, thereby affecting the relationship between the voltage V_{cond} and the voltage V_{ref}. When p̅q̅ is 0, V_{cond}<V_{ref}, the voltage output by the voltage comparator is at the low level, that is, the logic operation result is 0. When p̅q̅ is 1, V_{cond}>V_{ref}, the voltage output by the voltage comparator is at the high level, that is, the logic operation result is 1, thus implementing the NAND logic operation, and the Boolean logic operation result is p̅q̅.

When the Boolean logic operation is an OR logic operation of logical values p and q, the logical expression is p̅+̅q̅, under the circumstances, a is p, c is q, b is 1, and d is 1. Specifically, before performing the Boolean logic operation, both the memristor M₁ and the memristor M₂ are preset to the low resistance state. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor. When q is 0, the gate of the second transistor is grounded. When q is 1, the fixed voltage V_{DD} is applied to the gate of the second transistor. Under the circumstances, the current flowing through the fixed resistor R changes according to the variation of the input logical values p+q, thereby affecting the relationship between the voltage V_{cond} and the voltage V_{ref}. When p+q is 0, V_{cond}<V_{ref}, the voltage output by the voltage comparator is at the low level, that is, the logic operation result is 0. When a+b is 1, V_{cond}>V_{ref}, the voltage output by the voltage comparator is at the high level, that is, the logic operation result is 1, thus implementing the OR logic operation, and the Boolean logic operation result is p+q.

When the Boolean logic operation is an NOR logic operation of logical values p and q, the logical expression is p+q, under the circumstances, a is a logical negation of p, c is 0, b is a logical negation of q, and d is 0 or 1. Specifically, before performing the Boolean logic operation, the memristor M₁ is preset to the resistance state corresponding to the logical value which is the negation of q. When q is 1 (negation of q is 0), the memristor M₁ is preset to the high resistance state. When q is 0 (negation of q is 1), the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 1 (negation of p is 0), the gate of the first transistor is grounded. When p is 0 (negation of p is 1), the fixed voltage V_{DD} is applied to the gate of the first transistor, and the gate of the second transistor is grounded. Under the circumstances, the current flowing through the fixed resistor R changes according to the variation of the input logical values p̅+̅q̅, thereby affecting the relationship between the voltage V_{cond} and the voltage V_{ref}. When p̅+̅q̅ is 0, V_{cond}<V_{ref}, the voltage output by the voltage comparator is at the low level, that is, the logic operation result is 0. When p̅+̅q̅ is 1, V_{ref}>V_{ref}, the voltage output by the voltage comparator is at the high level, that is, the logic operation result is 1, thus implementing the NOR logic operation, and the Boolean logic operation result is p̅+̅q̅.

When the Boolean logic operation is a material implication logic operation of logical values p and q, the logical expression is p̅+q, under the circumstances, a is a logical negation of p, c is q, b is 1, and d is 1. Specifically, before performing the Boolean logic operation, both the memristor M₁ and the memristor M₂ are preset to the low resistance state. When performing the Boolean logic operation, the voltage Vᵣ is applied to the control terminal T₁ and the control terminal T₂ respectively, and the control terminal T₃ is grounded. When p is 1 (negation of p is 0), the gate of the first transistor is grounded. When p is 0 (negation of p is 1), the fixed voltage V_{DD} is applied to the gate of the first transistor. When q is 0, the gate of the second transistor is grounded. When q is 1, the fixed voltage V_{DD} is applied to the gate of the second transistor. Under the circumstances, the current flowing through the fixed resistor R changes according to the variation of the input logical values p̅+q, thereby affecting the relationship between the voltage V_{cond} and the voltage V_{ref}. When p̅+q is 0, V_{cond}<V_{ref}, the voltage output by the voltage comparator is at the low level, that is, the logic operation result is 0. When p̅+q is 1, V_{cond}>V_{ref}, the voltage output by the voltage comparator is at the high level, that is, the logic operation result is 1, thus implementing the material implication logic operation, and the Boolean logic operation result is p̅+q.

When the Boolean logic operation is a negative material implication logic operation of logical values p and q, the logical expression is pq, under the circumstances, a is p, c is 0, b is a logical negation of q, and d is 0 or 1. Specifically, before performing the Boolean logic operation, the memristor M₁ is preset to the resistance state corresponding to the logical value which is the negation of q. When q is 1 (negation of q is 0), the memristor M₁ is preset to the high resistance state. When q is 0 (negation of q is 1), the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor, and the gate of the second transistor is grounded. Under the circumstances, the current flowing through the fixed resistor R changes according to the variation of the input logical values pq̅, thereby affecting the relationship between the voltage V_{c} on d and the voltage V_{ref}. When pq̅ is 0, V_{cond}<V_{ref}, the voltage output by the voltage comparator is at the low level, that is, the logic operation result is 0; when pq̅ is 1, V_{cond}>V_{ref}, the voltage output by the voltage comparator is at the high level, that is, the logic operation result is 1, thus implementing the negative material implication logic operation, and the Boolean logic operation result is pq̅.

When the Boolean logic operation is a converse material implication logic operation of logical values p and q, the logical expression is p+q̅, under the circumstances, a is p, c is a logical negation of q, b is 1, and d is 1. Specifically, before performing the Boolean logic operation, both the memristor M₁ and the memristor M₂ are preset to the low resistance state. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor. When q is 1 (negation of q is 0), the gate of the second transistor is grounded. When q is 0 (negation of q is 1), the fixed voltage V_{DD} is applied to the gate of the second transistor. Under the circumstances, the current flowing through the fixed resistor R changes according to the variation of the input logical values p+q̅, thereby affecting the relationship between the voltage V_{cond} and the voltage V_{ref}. When p+q̅ is 0, V_{cond}<V_{ref}, the voltage output by the voltage comparator is at the low level, that is, the logic operation result is 0. When p+q̅ is 1, V_{cond}>V_{ref}, the voltage output by the voltage comparator is at the high level, that is, the logic operation result is 1, thus implementing the converse material implication logic operation, and the Boolean logic operation result is p+q̅.

When the Boolean logic operation is a converse negative material implication logic operation of logical values p and q, the logical expression is pq, under the circumstances, a is a logical negation of p, c is 0, b is q, and d is 0 or 1. Specifically, before performing the Boolean logic operation, the memristor M₁ is preset to the resistance state corresponding to the logical value q. When q is 0, the memristor M₁ is preset to the high resistance state. When q is 1, the memristor M₁ is preset to the low resistance state, and the memristor M₂ is preset to the high resistance state or the low resistance state, which is not limited here. When performing the Boolean logic operation, the voltage Vᵣ is applied to the control terminal T₁ and the control terminal T₂ respectively, and the control terminal T₃ is grounded. When p is 1 (negation of p is 0), the gate of the first transistor is grounded. When p is 0 (negation of p is 1), the fixed voltage V_{DD} is applied to the gate of the first transistor, and the gate of the second transistor is grounded. Under the circumstances, the current flowing through the fixed resistor R changes according to the variation of the input logical values pq̅, thereby affecting the relationship between the voltage V_{cond} and the voltage V_{ref}. When pq̅ is 0, V_{cond}<V_{ref}, the voltage output by the voltage comparator is at the low level, that is, the logic operation result is 0. When pq̅ is 1, V_{cond}>V_{ref}, the voltage output by the voltage comparator is at the high level, that is, the logic operation result is 1, thus implementing the converse negative material implication logic operation, and the Boolean logic operation result is pq̅.

When the Boolean logic operation is an XOR logic operation of logical values p and q, the logical expression is pq̅+pq̅, under the circumstances, a is a logical negation of p, c is p, b is q, and d is a logical negation of q. Specifically, before performing the Boolean logic operation, the memristor M₁ is preset to the resistance state corresponding to the logical value q. When q is 0, the memristor M₁ is preset to the high resistance state. When q is 1, the memristor M₁ is preset to the low resistance state, and the memristor M₂ is preset to the resistance state corresponding to the logical value of negation of q. When q is 1 (negation of q is 0), the memristor M₂ is preset to the high resistance state. When q is 0 (negation of q is 1), the memristor M₂ is preset to the low resistance state. When performing the Boolean logic operation, the voltage Vᵣ is applied to the control terminal T₁ and the control terminal T₂ respectively, and the control terminal T₃ is grounded. When p is 1 (negation of p is 0), the gate of the first transistor is grounded. When p is 0 (negation of p is 1), the fixed voltage V_{DD} is applied to the gate of the first transistor. When p is 0, the gate of the second transistor is grounded. When p is 1, the fixed voltage V_{DD} is applied to the gate of the second transistor. Under the circumstances, the current flowing through the fixed resistor R changes according to the variation of the input logical values pq̅+pq̅, thereby affecting the relationship between the voltage V_{cond} and the voltage V_{ref}. When p̅q+pq̅ is 0, Vₒnd<V_{ref}, the voltage output by the voltage comparator is at the low level, that is, the logic operation result is 1, thus implementing the XOR logic operation, and the Boolean logic operation result is p̅q+pq̅.

When the Boolean logic operation is an XNOR logic operation of logical values p and q, the logical expression is p̅q̅+pq, under the circumstances, a is p, c is a logical negation of p, b is q, and d is a logical negation of q. Specifically, before performing the Boolean logic operation, the memristor M₁ is preset to the resistance state corresponding to the logical value q. When q is 0, the memristor M₁ is preset to the high resistance state. When q is 1, the memristor M₁ is preset to the low resistance state, and the memristor M₂ is preset to the resistance state corresponding to the logical value of negation of q. When q is 1 (negation of q is 0), the memristor M₂ is preset to the high resistance state. When q is 0 (negation of q is 1), the memristor M₂ is preset to the low resistance state. When performing the Boolean logic operation, the voltage Vᵣ is applied to the control terminal T₁ and the control terminal T₂ respectively, and the control terminal T₃ is grounded. When p is 0, the gate of the first transistor is grounded. When p is 1, the fixed voltage V_{DD} is applied to the gate of the first transistor. When p is 1 (negation of p is 0), the gate of the second transistor is grounded. When p is 0 (negation of p is 1), the fixed voltage V_{DD} is applied to the gate of the second transistor. Under the circumstances, the current flowing through the fixed resistor R changes according to the variation of the input logical values p̅q̅+pq, thereby affecting the relationship between the voltage V_{cond} and the voltage V_{ref}. When p̅q̅+pq is 0, V_{cond}<V_{ref}, the voltage output by the voltage comparator is at the low level, that is, the logic operation result is 0. When p̅q̅+pq is 1, V_{cond}>V_{ref}, the voltage output by the voltage comparator is at the high level, that is, the logic operation result is 1, thus implementing the XNOR logic operation, and the Boolean logic operation result is p̅q̅+pq.

The circuit features a simple structure with a minimal number of elements and operational steps. The present disclosure allows for flexible selection of input variables to be retained for logical cascading in more complex application scenarios, thereby laying the foundation for complex logical operations.

In a third aspect, the present disclosure provides a Boolean logic operation device, including: a controller and the Boolean logic circuit provided in the first aspect of the present disclosure.

The controller is configured to execute the control method provided in the second aspect of the present disclosure.

Related technical solutions are the same as the Boolean logic circuit provided in the first aspect of the present disclosure and the control method provided in the second aspect of the present disclosure, which will not be elaborated here.

In a fourth aspect, the present disclosure provides a control system, including: a memory and a processor. The memory stores a computer program, and the processor executes the control method provided in the second aspect of the present disclosure when executing the computer program.

Related technical solutions are the same as the control method provided in the second aspect of the present disclosure, which will not be elaborated here.

In a fifth aspect, the present disclosure further provides a computer-readable storage medium. The computer-readable storage medium includes a stored computer program. When the computer program is executed by a processor, the computer program controls a device where the storage medium is located to execute the control method provided in the second aspect of the present disclosure.

Related technical solutions are the same as the control method provided in the second aspect of the present disclosure, which will not be elaborated here.

In a sixth aspect, the disclosure further provides a computer program product, including a computer program/instructions. When the computer program/instructions are executed by a processor, the control method provided in the second aspect of the present disclosure is implemented.

Related technical solutions are the same as the control method provided in the second aspect of the present disclosure, which will not be elaborated here.

In summary, the present disclosure provides a memristor-based four-input reconfigurable logic implementation method, which may complete any one of the 16 complete Boolean logics within two steps under a single operation scheme, and is easy to cascade. Meanwhile, the method may implement large-scale parallel computing in 1T1R arrays, and has great advantages in the process of implementing digital logic components such as full adders.

Those skilled in the art may easily understand that the above descriptions are only preferred embodiments of the present disclosure and are not configured to limit the present disclosure. Any modifications, equivalent substitutions and improvements made within the spirit and principles of the present disclosure should be included within the scope to be protected by the present disclosure.

What is claimed is:

1. A memristor-based Boolean logic circuit, comprising: a memristor M₁, a memristor M₂, a first transistor, a second transistor, a resistor, and a voltage comparator; wherein the memristor M₁ and the memristor M₂ are identical; the first transistor and the second transistor are identical and are NMOS transistors; a resistance value of the resistor is a low resistance state value of the memristor;
wherein a positive electrode of the memristor M₁ serves as a control terminal T₁, and a negative electrode is connected to a source of the first transistor; a positive electrode of the memristor M₂ serves as a control terminal T₂, and a negative electrode is connected to a source of the second transistor; drains of the first transistor and the second transistor are both connected to one end of the resistor, and the other end of the resistor serves as a control terminal T₃; a positive terminal of the voltage comparator is connected to a common node of the memristor M₁, the memristor M₂ and the resistor;
when performing a Boolean logic operation, the memristor M₁ is configured to store a logical value b; a negative terminal of the voltage comparator is configured to connect to a reference voltage V_{ref}; the memristor M₂ is configured to store a logical value d; the control terminal T₁ and the control terminal T₂ are respectively configured to connect to a voltage Vᵣ; a gate of the first transistor is configured to connect to a gate voltage corresponding to a logical value a; a gate of the second transistor is configured to connect to a gate voltage corresponding to a logical value c; the control terminal T₃ is used for grounding; an output terminal of the voltage comparator is configured to output a corresponding Boolean logic operation result;
wherein V_{ref} and Vᵣ satisfy: (R_{H}+R_{L})Vᵣ/(2R_{H}+R_{L})<V_{ref}<2Vᵣ/3, R_{H} and R_{L} are respectively a high resistance state value and the low resistance state value of the memristor; a gate voltage corresponding to a logical value 0 is a voltage V_{G} which is less than a transistor enabling voltage, and a gate voltage corresponding to a logical value 1 is a voltage V_{DD} which is greater than or equal to the transistor enabling voltage.

2. The memristor-based Boolean logic circuit according to claim 1, wherein when the Boolean logic operation is a true logic operation, a is 1, c is 0 or 1, b is 1, and d is 0 or 1;
when the Boolean logic operation is a false logic operation, a is 0, c is 0, b is 0 or 1, and d is 0 or 1;
when the Boolean logic operation is a p logic operation, a is p, c is 0, b is 1, and d is 0 or 1;
when the Boolean logic operation is a q logic operation, a is 0, c is q, b is 0 or 1, and d is 1;
when the Boolean logic operation is a negation of p, a is a logical negation of p, c is 0, b is 1, and d is 0 or 1;
when the Boolean logic operation is a negation of q, a is 0, c is a logical negation of q, b is 0 or 1, and d is 1;
when the Boolean logic operation is an AND logic operation of logical values p and q, a is p, c is 0, b is q, and d is 0 or 1;
when the Boolean logic operation is an NAND logic operation of the logical values p and q, a is a logical negation of p, c is a logical negation of q, b is 1, and d is 1;
when the Boolean logic operation is an OR logic operation of the logical values p and q, a is p, c is q, b is 1, and d is 1;
when the Boolean logic operation is an NOR logic operation of the logical values p and q, a is a logical negation of p, c is 0, b is a logical negation of q, and d is 0 or 1;
when the Boolean logic operation is a material implication logic operation of the logical values p and q, a is a logical negation of p, c is q, b is 1, and d is 1;
when the Boolean logic operation is a negative material implication logic operation of the logical values p and q, a is p, c is 0, b is a logical negation of q, and d is 0 or 1;
when the Boolean logic operation is a converse material implication logic operation of the logical values p and q, a is p, c is a logical negation of q, b is 1, and d is 1;
when the Boolean logic operation is a converse negative material implication logic operation of the logical values p and q, a is a logical negation of p, c is 0, b is q, and d is 0 or 1;
when the Boolean logic operation is an XOR logic operation of the logical values p and q, a is a logical negation of p, c is p, b is q, and d is a logical negation of q;
when the Boolean logic operation is an XNOR logic operation of the logical values p and q, a is p, c is a logical negation of p, b is q, and d is a logical negation of q.

3. A control method for a memristor-based Boolean logic circuit, wherein the memristor-based Boolean logic circuit is the memristor-based Boolean logic circuit according to claim 1, the control method comprises a Boolean logic operation: applying the voltage Vᵣ to the control terminal T₁ and the control terminal T₂ respectively, applying the gate voltage corresponding to the logical value a to the gate of the first transistor, applying the gate voltage corresponding to the logical value c to the gate of the second transistor, grounding the control terminal T₃, and reading a corresponding Boolean logic operation result at the output terminal of the voltage comparator;
wherein the memristor M₁ in the Boolean logic circuit stores the logical value b, and the memristor M₂ of the Boolean logic circuit stores the logical value d; the negative terminal of the voltage comparator in the Boolean logic circuit is connected to the reference voltage V_{ref}; V_{ref} and Vᵣ satisfy: (R_{H}+R_{L})Vᵣ/(2R_{H}+R_{L})<V_{ref}<2Vᵣ/3, R_{H} and R_{L} are the high resistance state value and the low resistance state value of the memristor respectively; the gate voltage corresponding to the logical value 0 is the voltage V_{G} less than the transistor enabling voltage, and the gate voltage corresponding to the logical value 1 is the voltage V_{DD} greater than or equal to the transistor enabling voltage.

4. The control method according to claim 3, further comprising: an initialization memristor operation executed before the Boolean logic operation;
the initialization memristor operation comprises: writing the logical value b into the memristor M₁, and writing the logical value d into the memristor M₂;
wherein a corresponding logical value is written by setting high and low resistance states of the memristor; the high resistance state of the memristor corresponds to the logical value 0, and the low resistance state corresponds to the logical value 1.

5. The control method according to claim 4, wherein the operation of writing the logical value b into the memristor M₁ comprises:
when b is 0, the control terminal T₁ is grounded, the control terminal T₂ is set to a floating state, and a fixed voltage V_{q} is connected to the control terminal T₃, the voltage V_{DD} is applied to the gates of the first transistor and the second transistor, thereby writing the logical value b into the memristor M₁;
when b is 1, a fixed voltage Vₚ is connected to the control terminal T₁, the control terminal T₂ is set to the floating state, and the control terminal T₃ is grounded, the voltage V_{DD} is applied to the gates of the first transistor and the second transistor, thereby writing the logical value b into the memristor M₁;
wherein V_{q}>2|Vᵣₑₛₑₜ|; Vₚ>(R_{H}+R_{L})Vₛₑₜ/R_{H}; Vᵣₑₛₑₜ is a threshold for the memristor to convert from the low resistance state to the high resistance state; Vₛₑₜ is a threshold for the memristor to convert from the high resistance state to the low resistance state; R_{H} is the high resistance state value of the memristor; R_{L} is the low resistance state value of the memristor.

6. The control method according to claim 4, wherein the operation of writing the logical value d into the memristor M₂ comprises:
when d is 0, the control terminal T₁ is set to a floating state, the control terminal T₂ is grounded, and a fixed voltage V_{q} is connected to the control terminal T₃, the voltage V_{DD} is applied to the gates of the first transistor and the second transistor, thereby writing the logical value d into the memristor M₂;
when d is 1, the control terminal T₁ is set to the floating state, a fixed voltage Vₚ is connected to the control terminal T₂, and the control terminal T₃ is grounded, the voltage V_{DD} is applied to the gates of the first transistor and the second transistor, thereby writing the logical value d into the memristor M₂;
wherein V_{q}>2|Vᵣₑₛₑₜ|; Vₚ>(R_{H}+R_{L})Vₛₑₜ/R_{H}; Vᵣₑₛₑₜ is a threshold for the memristor to convert from the low resistance state to the high resistance state; Vₛₑₜ is a threshold for the memristor to convert from the high resistance state to the low resistance state; R_{H} is the high resistance state value of the memristor; R_{L} is the low resistance state value of the memristor.

7. The control method according to claim 3, wherein when the Boolean logic operation is a true logic operation, a is 1, c is 0 or 1, b is 1, and d is 0 or 1;
when the Boolean logic operation is a false logic operation, a is 0, c is 0, b is 0 or 1, and d is 0 or 1;
when the Boolean logic operation is a p logic operation, a is p, c is 0, b is 1, and d is 0 or 1;
when the Boolean logic operation is a q logic operation, a is 0, c is q, b is 0 or 1, and d is 1;
when the Boolean logic operation is a negation of p, a is a logical negation of p, c is 0,
b is 1, and d is 0 or 1;
when the Boolean logic operation is a negation of q, a is 0, c is a logical negation of q,
b is 0 or 1, and d is 1;
when the Boolean logic operation is an AND logic operation of the logical values p and q, a is p, c is 0, b is q, and d is 0 or 1;
when the Boolean logic operation is an NAND logic operation of the logical values p and q, a is a logical negation of p, c is a logical negation of q, b is 1, and d is 1;
when the Boolean logic operation is an OR logic operation of the logical values p and q, a is p, c is q, b is 1, and dis 1;
when the Boolean logic operation is an NOR logic operation of the logical values p and q, a is a logical negation of p, c is 0, b is a logical negation of q, and d is 0 or 1;
when the Boolean logic operation is a material implication logic operation of the logical values p and q, a is a logical negation of p, c is q, b is 1, and d is 1;
when the Boolean logic operation is a negative material implication logic operation of the logical values p and q, a is p, c is 0, b is a logical negation of q, and d is 0 or 1;
when the Boolean logic operation is a converse material implication logic operation of the logical values p and q, a is p, c is a logical negation of q, b is 1, and d is 1;
when the Boolean logic operation is a converse negative material implication logic operation of the logical values p and q, a is a logical negation of p, c is 0, b is q, and d is 0 or 1;
when the Boolean logic operation is an XOR logic operation of the logical values p and q, a is a logical negation of p, c is p, b is q, and d is a logical negation of q;
when the Boolean logic operation is an XNOR logic operation of the logical values p and q, a is p, c is a logical negation of p, b is q, and d is a logical negation of q.

8. A Boolean logic operation device, comprising: a controller and the memristor-based Boolean logic circuit according to claim 1;
wherein the controller is configured to execute the control method according to claim 3.

9. A control system, comprising: a memory and a processor, wherein the memory stores a computer program, the processor executes the control method according to claim 3 when executing the computer program.

10. A computer program product, comprising a computer program/instructions, wherein the computer program/instructions implement the control method according to claim 3 when executed by a processor.
